(19) United States
(12) Patent Application Publication
(10) Pub. No.: US 2026/0161086 A1
(43) Pub. Date: Jun. 11, 2026

(54) METHODS AND ARTICLE FOR STORING ORGANIC TIN COMPOUNDS

(71) Applicants: Mitsubishi Chemical Corporation, Tokyo (JP); Gelest, Inc., Morrisville, PA (US)

(72) Inventors: Li YANG, Belle Mead, NJ (US); Tsuyoshi NAGASAKA, Tokyo (JP); Yuta HIOKI, Tokyo (JP); Soichiro OMIZU, Tokyo (JP)

(21) Appl. No.: 19/063,998

(22) Filed: Feb. 26, 2025

Related U.S. Application Data
(60) Provisional application No. 63/558,777, filed on Feb. 28, 2024.

(51) Int. Cl. G03F 7/16; B08B 3/08; B65D 65/38; B65D 81/20; B65D 81/26; C07F 7/22; C11D 7/08; H10P 76/00

(52) U.S. Cl. CPC G03F 7/167; B08B 3/08; B65D 65/38; B65D 81/2076; B65D 81/263; C07F 7/2284; C07F 7/2296; C11D 7/08; H10P 76/00

(57) ABSTRACT

An article containing an organic tin compound in an industrially usable container is provided, in which the container is sealable, and the part of the container in contact with the organic tin compound is made of stainless steel with a specific surface structure that has been electrolytically polished. This article makes it possible to store organic tin compounds with high reactivity while maintaining their purity for a long period of time.

### CROSS REFERENCE TO RELATED APPLICATION

This application claims priority to co-pending U.S. provisional patent application No. 63/558,777, filed Feb. 28, 2024, the disclosure of which is herein incorporated by reference in its entirety.

### BACKGROUND OF THE INVENTION

### Technical Field

The present disclosure relates to a stainless steel container and a method for storing organic tin compounds for storage, supply, and transportation in processes such as semiconductor manufacturing. It also relates to a method for storing organic tin compounds using such a container.

Furthermore, this relates to methods for storing, supplying, transporting, and extracting monoalkyltin compounds that have a specific structure and are reactive with water and other substances, in specific metal containers without compromising their purity.

### Background Art

In recent years, there has been a growing demand for ultra-high-purity liquid or solid materials in the precise manufacturing processes of information electronics and semiconductors. Consequently, there is a strong need to avoid purity degradation and impurity contamination in each process, including manufacturing, purification, storage, transportation, transfer, and usage.

For materials with particularly high reactivity (to water, air, light, etc.), more advanced management is required, especially during long-term storage, as degradation due to decomposition becomes a more significant issue across the aforementioned processes. When storing such compounds, metal containers, such as stainless steel (SUS), are used, sometimes with resin coating, due to considerations of high sealability, pressure resistance, high strength, formability, and cost (Patent Document 1). Additionally, while the examples in Patent Document 2 mention storing high-purity distilled CVD materials, specifically metal alkoxides, in electrolytically polished SUS316 containers, they focus on improving thermal stability by removing volatile impurities from the metal alkoxide. For the exemplified tetramethoxytin, there is no suggestion regarding the stabilizing effect of the storage container. Patent Document 3 describes thermal stability tests of tetraaminotin compounds in stainless steel containers, but these tests were not conducted on more reactive monoalkyltin compounds, and there is no indication of any relationship with the stainless steel of the storage container.

### PRIOR ART DOCUMENTS

[Patent Literature 1]U.S. Patent Publication No. 2015-0210430
[Patent Literature 2]U.S. Patent Publication No. 6100415
[Patent Literature 3]U.S. Patent Publication No. 2022-0306657

### Problems to be Solved by the Invention

Until now, there has been insufficient consideration regarding containers and storage methods that can maintain high purity while storing highly decomposable materials such as monoalkyltin compounds with specific structures. Specifically, for tin compounds that experience purity degradation in common stainless steel (SUS) storage containers, there were no methods to store them for long periods while maintaining high purity. The method of coating SUS surfaces with resin is not appropriate, especially for repeated use, due to concerns about contamination from the resin.

### SUMMARY OF THE INVENTION

This invention was made in light of these circumstances to provide a storage method that enables long-term storage of highly reactive monoalkyltin compounds while maintaining their purity, using stainless steel containers with specific surface structures that are industrially viable. The containers used in the storage method according to this disclosure are also useful for manufacturing, purification, transportation, transfer, and use of monoalkyltin compounds, and such containers are also provided. Furthermore, articles containing these highly reactive monoalkyltin compounds sealed in such containers are useful for the high-quality manufacturing, purification, storage, transportation, transfer, and use of organic tin compounds.

### Means to Solve the Problems

The inventors, after intensive research considering these circumstances, discovered that when using containers with specific surface structures of stainless steel, specifically electrolytically polished stainless steel (SUS-EP), in contact with the monoalkyltin compounds to be stored, it is possible to store the monoalkyltin compounds while maintaining their purity. Moreover, articles containing these highly reactive monoalkyltin compounds sealed in such containers are useful for the high-quality manufacturing, purification, storage, transportation, transfer, and use of monoalkyltin compounds.

Aspects of the disclosure relate to an article comprising an organic tin compound sealed in a container (C1), wherein the organic tin compound is an organic tin compound having formula (A1) with a purity of 95 mol % or higher, the container (C1) is a sealed container, and the part of the container in contact with the organic tin compound is electrolytically polished stainless steel.

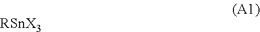

In formula (A1), R is an organic group having 1 to 30 carbon atoms which may be substituted with a halogen, oxygen atom, or nitrogen atom, X is selected from a halogen atom, OR′, and NR′₂, and each R′ group may be the same or different and is an organic group having 1 to 10 carbon atoms which may be substituted with a halogen, oxygen atom, or nitrogen atom. When there are multiple R′ groups in the molecule, they may have different structures from each other or may be bonded to form a cyclic structure. Also, R and one X may be bonded to have a cyclic structure.

Further aspects of the disclosure are directed to an article comprising an organic tin compound sealed in a container (C2), wherein the organic tin compound is an organic tin compound having formula (A1) with a purity of 95 mol % or higher, the container (C2) is a sealed container, and the part of the container in contact with the organic tin compound is a stainless steel container that satisfies the following Condition 1.

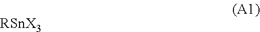

In formula (A1), R is an organic group having 1 to 30 carbon atoms which may be substituted with a halogen, oxygen atom, or nitrogen atom, X is selected from a halogen atom, OR′, and NR′₂, and each R′ group may be the same or different and is an organic group having 1 to 10 carbon atoms which may be substituted with a halogen, oxygen atom, or nitrogen atom. When there are multiple R′ groups in the molecule, they may have different structures from each other or may be bonded to form a cyclic structure. Also, R and one X may be bonded to have a cyclic structure.

### (Condition 1)

In the elemental composition analysis of the stainless steel by XPS,
when Cr1 represents the maximum Cr composition (at %) in the depth range of 0 nm to 15 nm, and
when Cr2 represents the maximum Cr composition (at %) in the depth range of 15 nm to 30 nm,
Cr1/Cr2 is 1.2 or more.

Additional aspects of the disclosure are directed to a method for storing an organic tin compound by putting it in a container (C1), wherein the organic tin compound is an organic tin compound having formula (A1) with a purity of 95 mol % or higher, the container (C1) is a sealed container, and the part in contact with the organic tin compound is electrolytically polished stainless steel.

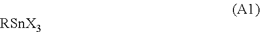

In formula (A1), R is an organic group having 1 to 30 carbon atoms which may be substituted with a halogen, oxygen atom, or nitrogen atom, X is selected from a halogen atom, OR′, and NR′₂, and each R′ group may be the same or different and is an organic group having 1 to 10 carbon atoms which may be substituted with a halogen, oxygen atom, or nitrogen atom. When there are multiple R′ groups in the molecule, they may have different structures from each other or may be bonded to form a cyclic structure. Also, R and one X may be bonded to have a cyclic structure.

Advantageous refinements of the disclosure, which can be implemented alone or in combination, are specified in the dependent claims.

In summary, the following embodiments are proposed as particularly preferred in the scope of the present disclosure:
[1] An article comprising an organic tin compound sealed in a container (C1), wherein the organic tin compound is an organic tin compound having formula (A1) with a purity of 95 mol % or higher, the container (C1) is a sealed container, and the part of the container in contact with the organic tin compound is electrolytically polished stainless steel.

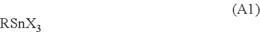

In formula (A1), R is an organic group having 1 to 30 carbon atoms which may be substituted with halogen, oxygen atom, or nitrogen atom, X is selected from a halogen atom, OR′, or NR′₂, and each R′ group may be the same or different and is an organic group having 1 to 10 carbon atoms which may be substituted with a halogen, oxygen atom, or nitrogen atom. When there are multiple R′ groups in the molecule, they may have different structures from each other or may be bonded to form a cyclic structure. Also, R and one X may be bonded to have a cyclic structure.

[2] The article according to [1], wherein an inert gas is enclosed in the container (C1).

[3] An article comprising an organic tin compound sealed in a container (C2), wherein the organic tin compound is an organic tin compound having formula (A1) with a purity of 95 mol % or higher, the container (C2) is a sealed container, and the part of the container in contact with the organic tin compound is a stainless steel container that satisfies the following Condition 1:

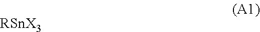

In formula (A1), R is an organic group having 1 to 30 carbon atoms which may be substituted with a halogen, oxygen atom, or nitrogen atom, X is selected from a halogen atom, OR′, or NR′₂, and each R′ group may be the same or different and is an organic group having 1 to 10 carbon atoms which may be substituted with a halogen, oxygen atom, or nitrogen atom. When there are multiple R′ groups in the molecule, they may have different structures from each other or may be bonded to form a cyclic structure. Also, R and one X may be bonded to have a cyclic structure.

### (Condition 1)

In the elemental composition analysis of the stainless steel by XPS,
When Cr1 represents a maximum Cr composition (at %) in the depth range of 0 nm to 15 nm,
When Cr2 represents a maximum Cr composition (at %) in the depth range of 15 nm to 30 nm, Cr1/Cr2 is 1.2 or more.

[4] The article according to [3], wherein an inert gas is enclosed in the container (C2).

[5] The article according to [1] or [3], wherein the inert gas is argon.

[6] The article according to [1] or [3], wherein in the surface elemental analysis of the stainless steel by XPS, the composition ratio (at %) of Cr to Fe is 0.30 or more.

[7] The article according to [1] or [3], wherein in the surface elemental analysis of the stainless steel by XPS, when the total amount of Cr, Fe, Ni, Mo, and O is set to 100 (at %), the amount of Cr is 7 (at %) or more.

[8] The article according to [1] or [3], wherein the stainless steel is SUS316.

[9] The article according to [1] or [3], wherein the surface roughness Sa (arithmetic mean height) of the stainless steel is 200 nm or less.

[10] The article according to [1] or [3], wherein the surface roughness Sq (root mean square height) of the stainless steel is 200 nm or less.

[11] The article according to [1] or [3], wherein the container (C1) or the container (C2) has two or more valves.

[12] The article according to [1] or [3], wherein the container (Cl) or the container (C2) is a container for supplying the organic tin compound represented by formula (A1) by connecting the container to a CVD apparatus.

[13]A storage method for the article according to [1] or [3], wherein the article is stored at 0° C. to 25° C.

[14]A storage method for the article according to [1] or [3], comprising sealing the organic tin compound having formula (A1) in the container (C1 or C2) that has been cleaned by a method including the following Steps 1 and 2:
Step 1: Cleaning with acidic aqueous solution
Step 2: Cleaning with ultrapure water

[15]A storage method for the article according to [1] or [3], comprising cleaning the container (C1 or C2) by a method including the following Steps 1 and 2 after taking out or removing the organic tin compound represented by formula (A1) from the article of [1] or [3], and then re-sealing the organic tin compound represented by formula (A1) in the container:
Step 1: Cleaning with acidic aqueous solution
Step 2: Cleaning with ultrapure water

[16]A method for storing an organic tin compound by putting it in a container (C1), wherein the organic tin compound is an organic tin compound having formula (A1) with a purity of 95 mol % or higher, the container (C1) is a sealed container, and the part of the container in contact with the organic tin compound is electrolytically polished stainless steel.

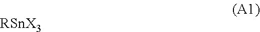

In formula (A1), R is an organic group having 1 to 30 carbon atoms which may be substituted with halogen, oxygen atom, or nitrogen atom, X is selected from a halogen atom, OR′, or NR′₂, and each R′ group may be the same or different and is an organic group having 1 to 10 carbon atoms which may be substituted with a halogen, oxygen atom, or nitrogen atom. When there are multiple R′ groups in the molecule, they may have different structures from each other or may be bonded to form a cyclic structure. Also, R and one X may be bonded to have a cyclic structure.

[17]A method for manufacturing a coating liquid, comprising removing the organic tin compound represented by formula (A1) from the article of [1] or [3] and mixing it with an organic solvent.

[18]A patterning method for semiconductors comprising the steps of applying the coating liquid produced in [17] onto a substrate to form a thin film; irradiating said thin film with a chemical beam of actinic radiation; and developing the exposed thin film.

[19]A method for forming a pattern of a semiconductor, comprising a step of removing the organic tin compound represented by formula (A1) from the article of [1] or [3] and forming a thin film by depositing it on a substrate, a step of irradiating the thin film with actinic radiation, and a step of developing the exposed thin film.

### Advantageous Effects of the Invention

With the storage method of the present disclosure, it is possible to store highly reactive organic tin compounds while maintaining their purity over an extended period, using containers made of stainless steel with specific surface structures that are industrially usable. The containers of the present disclosure are not only useful for storage but also as containers for processes such as manufacturing, purification, storage, transportation, transfer, and usage of organic tin compounds.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is an exploded oblique view of a storage container for organic tin compounds according to one embodiment of the present disclosure;

FIG. 2 is an exploded oblique view of a precursor CVD gas supply container according to one embodiment of the present disclosure;

FIG. 3 is a cross-sectional view of a precursor CVD gas supply container, according to one embodiment of the present disclosure;

FIG. 4(A) is a depth profile of the elemental composition (at %) of SUS316-EP; and

FIG. 4(B) is a depth profile of the elemental composition (at %) of SUS316.

### DETAILED DESCRIPTION OF THE INVENTION

The following is a more detailed description of the embodiments of the present disclosure, but the present disclosure is not limited to these embodiments.

In this specification, when expressing “Y to Z” (where Y and Z are arbitrary numbers), unless otherwise stated, it includes the meaning of “preferably greater than Y” or “preferably less than Z” in addition to the meaning of “preferably Y or more and Z or less.”

Also, when expressing “Y or more” (where Y is an arbitrary number) or “Z or less” (where Z is an arbitrary number), it includes the meaning of “preferably greater than Y” or “preferably less than Z.” Furthermore, “x and/or y” (where x and y are arbitrary components) means that it includes at least one of x and y, x only, y only, or both x and y.

In addition, regarding the numerical ranges described in stages in this specification, the upper limit value or lower limit value of one numerical range can be arbitrarily combined with the upper limit value or lower limit value of another numerical range. Also, the upper limit value or lower limit value of the numerical range described in this specification can be replaced with the values shown in the examples.

Unless otherwise stated, any numerical value is to be understood as being modified in all instances by the term “about.” Thus, a numerical value typically includes 10% of the recited value. For example, the recitation of a temperature such as “10° C.” or “about 10° C.” includes 9° C. and 11° C. and all temperatures there between.

One embodiment of the method for storing organic tin compounds of the present disclosure (hereinafter sometimes referred to as “the present storage method”) is a method for storing an organic tin compound in a container.

The following explains this storage method.

### <Method for Storing Organic Tin Compounds>

### [Definition of Storage]

Here, the storage of organic tin compounds refers to the operation of keeping an organic tin compound in a sealed container for a certain period of time. For example, if an organic tin compound is kept in the same container for a certain period of time in processes such as manufacturing, purification, storage, transportation, transfer, and usage, it can be considered as storage.

### [Storage Period]

There is no particular limitation on the period of storage, but in addition to short-term storage such as 1 day, 3 days, 7 days, 15 days, and 1 month, it is preferable to be able to store it for long periods such as 1 month, 3 months, 6 months, and 1 year, and in some cases, it is more preferable to be able to store it for 5 years or even 10 years as needed. Short-term storage is important when an organic tin compound is temporarily kept in the same container for manufacturing, purification, transfer, etc., and long-term storage is often important when an organic tin compound is kept in the same container for a long storage time, transportation, usage, etc. As an evaluation method for the purity change of organic tin compounds due to short- to long-term storage, for example, by confirming the purity change after storing the compound for 1 month, it is possible to evaluate both short- and long-term storage.

### [Storage Conditions]

Organic tin compounds are preferably stored in a sealed container under an inert gas atmosphere such as nitrogen or argon to suppress purity degradation due to the aforementioned decomposition reaction. Among the inert gases, argon, which has a high density and is less likely to be replaced by air or water, is preferable. As for the upper limit of the storage temperature, it is preferably 40° C. or less, more preferably 30° C. or less, further preferably 25° C. or less, particularly preferably 15° C. or less, and further preferably 10° C. or less. As for the lower limit of the temperature, it is preferably a temperature of −10° C. or higher. In some cases, the storage is performed at about 0° C. to about 25° C. In some cases, it is possible to suppress the decomposition reaction of the organic tin compound by storing it at low temperatures. On the other hand, if the temperature is too low, especially when the organic tin compound is a liquid at room temperature, there is a tendency for problems to occur during the extraction process when it solidifies during storage.

### [Decomposition Rate During Storage]

The decomposition rate during storage is represented by the purity degradation rate [(purity before storage)−(purity after 1 month of storage)] when the organic tin compound to be stored is sealed in a container for 1 month, as shown in the examples described below. As for the preferred range of the decomposition rate, it is preferably 7 mol % or less, more preferably 5 mol % or less, further preferably 3 mol % or less, further preferably 2 mol % or less, further preferably 1 mol % or less, further preferably 0.80 mol % or less, further preferably 0.50 mol % or less, further preferably 0.30 mol % or less, further preferably 0.10 mol % or less, and further preferably 0.05 mol % or less. In addition to the decomposition rate, the examples below show the composition of each decomposition product, and depending on the structure of the decomposition product, there are cases when it has a negative impact on the use of semiconductor materials or resist materials, or further promotes decomposition during storage, and in such cases, it may be necessary to manage the occurrence amount more strictly. In that case, as for the increase in the amount of each decomposition product, it is preferably 0.50 mol % or less, more preferably 0.30 mol % or less, further preferably 0.10 mol % or less, and further preferably 0.05 mol % or less.

### [Metal Component Leaching and Impurity Mixing During Storage]

Metal component leaching during storage can be represented by the change in the amount of metal components contained in the organic tin compound when the compound to be stored is sealed in a container for 1 month, as shown in the examples described below. As for the specific analysis method for the amount of metal components, ICP-MASS analysis can be used, and the normal detection limit is approximately 1 ppb (mass ppb, ng/g) for each metal. As for the preferred range of the amount of metal leaching from the container, it is preferably 1000 ppb or less, more preferably 100 ppb or less, further preferably 10 ppb or less, and further preferably 1 ppb or less.

From the perspective of container corrosion and degradation, it is preferable for the rate of change in mass (g) of the stainless steel that was in contact with the organic tin compound when the compound was stored in the container for 1 month to be small. In other words, the rate of change (%) is represented by “change in mass (g) before and after storage/mass (g) before storage x 100.” As for the preferred range of mass change, it is preferably +0.1% or less, more preferably 0.05% or less, and further preferably +0.010% or less. Additionally, it is preferable from the perspective of container corrosion and degradation that no discoloration, corrosion, dissolution, or damage is observed when visually checking the surface of the stainless steel that was in contact with the organic tin compound.

### [Change in Organic Tin Compounds During Storage]

During storage, in addition to changes in purity and impurities, it is preferable that no changes such as discoloration or cloudiness occur, especially when storing transparent and low-colored liquid compounds. Specifically, in the aforementioned 1-month storage, it is preferable for the change in the APHA value of the organic tin compound to be 50 or less, and more preferably 30 or less. Also, it is preferable for no cloudiness to be observed when visually checking for cloudiness.

The following is a description of the organic tin compounds that are the target of storage using the aforementioned storage method.

### <Organic Tin Compounds>

Organic tin compounds are compounds that have at least one tin atom, carbon atom, hydrogen atom, and C—H bond in their molecules. The organic tin compounds used in this embodiment are often flammable at room temperature and easily react with water and air. They also tend to undergo transmetallation, a reaction in which the central metal is replaced by another metal. In particular, compounds with Sn—C bonds have a low Sn—C bond energy and can easily decompose due to heat or light. Additionally, compounds with hydrolysable groups can easily undergo hydrolysis, forming tin compounds with Sn—O—Sn and Sn—OH bonds, such as stanoxanes. These compounds with Sn—O—Sn and Sn—OH bonds can further react with other Sn compounds, forming oligomers, clusters, aggregates, and can undergo further degradation. Furthermore, organic tin compounds have the property where the valence of the tin atom can easily change between 2 and 4, and when in contact with materials that promote oxidation-reduction reactions during storage, by-products with changed valences of the organic tin compounds can occur. Similarly, the oxidation-reduction reaction of organic tin compounds can lead to the progression of oxidation-reduction of the storage materials, resulting in corrosion, leaching, and degradation. In particular, liquid organic tin compounds during storage have more contact with the storage materials, making it easier for issues such as accelerated decomposition due to contact with the materials and purity degradation due to the leaching of components from the materials to occur.

Among organic tin compounds, those used as precursors for extreme ultraviolet (EUV) resists require high purity (e.g., 99% or higher) and strict management of the amounts of impurities and metals they contain. Therefore, it is necessary to minimize impurities such as metals, halogen atoms, and decomposition products of organic tin compounds. To maintain the purity of organic tin compounds, it is necessary to employ an appropriate storage method. In particular, when storing liquid organic tin compounds, there is a greater concern about the leaching of metal components from the storage containers, requiring stricter management.

As organic tin compounds used as precursors for EUV resists or as synthetic intermediates, compounds having formula (I) are preferably used.

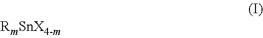

In formula (I), R is an organic group having 1 to 30 carbon atoms, which may be substituted with a halogen, oxygen, or nitrogen atoms. X is selected from halogen atoms, OR′, or NR′₂. Each R′ group may be the same or different, and is an organic group having 1 to 10 carbon atoms, which may be substituted with halogen, oxygen, or nitrogen atoms. When there are multiple R′ groups in the molecule, they may have different structures or may be bonded to each other to form a cyclic structure. m is an integer from 0 to 2. When m=1, R and one X group may be bonded to form a cyclic structure.

Tin compounds having formula (I) have both a substituted group R with Sn—C bonds and a substituted group X with hydrolysable groups, making them more reactive with water and air compared to typical organic tin compounds and more difficult to store. Additionally, they have low compound stability, making them prone to disproportionation reactions and the formation of decomposition products. In particular, when the contact parts of the container are made of metal, these decomposition reactions can be accelerated, requiring careful selection of materials. As mentioned earlier, when storing liquid organic tin compounds, there is a greater concern about the leaching of metal components from the storage containers, requiring stricter management.

### [Substituted Group R]

Substituted group R is an organic group having 1 to 30 carbon atoms, which may be substituted with halogen, oxygen, or nitrogen atoms. Considering the ease of R group detachment and volatilization of the R component during EUV exposure, the number of carbon atoms in R is preferably 30 or less as an upper limit, more preferably 20 or less, and further preferably 10 or less. From the perspective of the stability of the detached component, the lower limit is preferably 1 or more, more preferably 2 or more, and further preferably 3 or more.

Substituted group R may also be substituted with O, N, halogen, or other heteroatoms, and including these heteroatoms can increase the compound's decomposition sensitivity to EUV light, improving resist performance in terms of sensitivity.

Preferred specific examples of substituted group R include methyl, ethyl, propyl, isopropyl, butyl, isobutyl, sec-butyl, tert-butyl, pentyl, hexyl, cyclopentyl, cyclohexyl, and other alkyl groups; phenyl, trityl, naphthyl, and other aryl groups; benzyl, phenethyl, alpha-methylbenzyl, 2-phenyl-2-propyl, and other aralkyl groups; vinyl, 1-propenyl, allyl, 3-butenyl, and other alkenyl groups; 2-fluoroethyl, 2-iodoethyl, and other halogen-substituted alkyl groups, etc.

Further examples of structures include the following compounds. R^{a} and R^{b} in the compounds below are organic groups having 1 to 10 carbon atoms, which may be substituted with halogen, oxygen, nitrogen, or other heteroatoms. Substituent A on the aromatic ring is a halogen atom or an organic substituent group containing 1 to 10 carbon atoms, O, or N atoms.

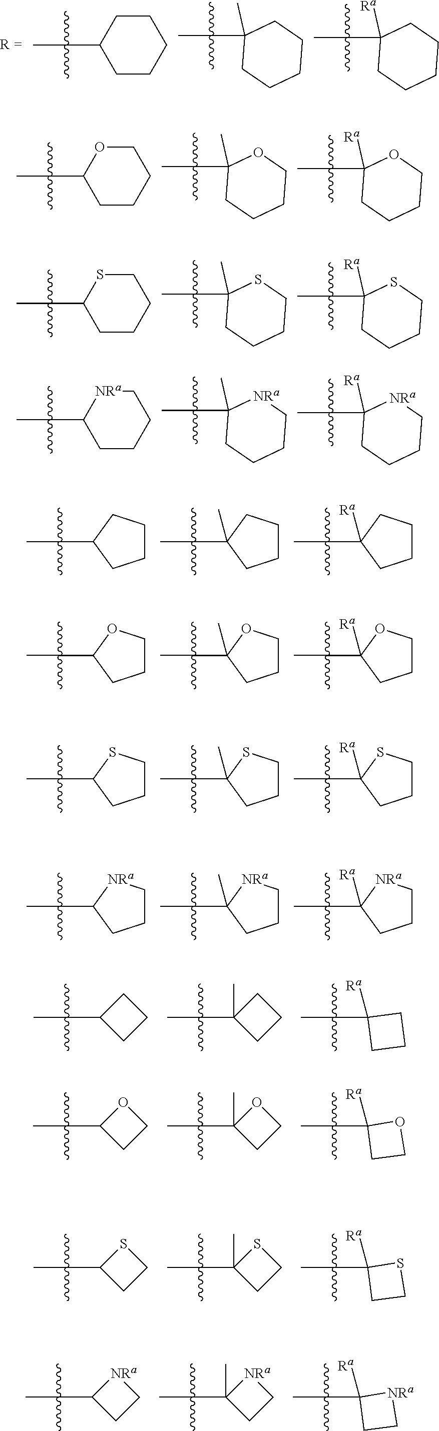

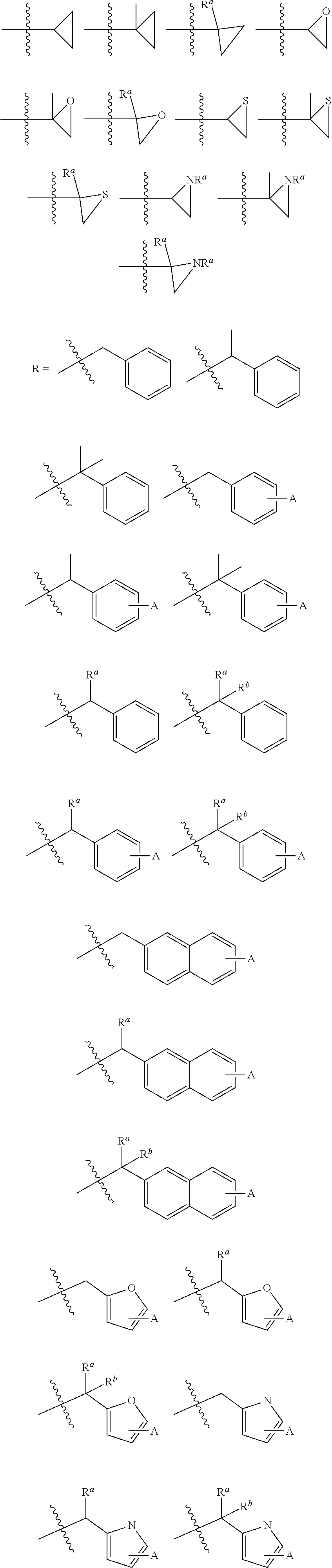

The aforementioned substituted group R can be classified into primary substituted groups R¹, secondary substituted groups R², and tertiary substituted groups R³, and they are typically alkyl or aralkyl groups. Preferred examples of each classification are as follows: primary substituted groups R¹: methyl, ethyl, n-propyl, n-butyl, isobutyl, benzyl, phenethyl, etc.; secondary substituted groups R²: isopropyl, sec-butyl, cyclopentyl, cyclohexyl, cycloheptyl, alpha-methylbenzyl, etc.; tertiary substituted groups R³: tert-butyl, tert-amyl, 1-methyl-cyclopentyl, 1-methyl-cyclohexyl, 2-phenyl-2-propyl, etc.

These groups can exhibit different characteristics when used as resist materials. Taking alkyl groups as a representative example, secondary alkyl groups R² and tertiary alkyl groups R³ are preferred from the perspective of sensitivity (light reactivity) when used as EUV resist materials. From the perspective of hydrophobicity, a tertiary alkyl group R³ is the most effective in increasing hydrophobicity near the tin atom, which is advantageous from the perspective of controlling solubility. However, in cases where hydrophobicity is too high, a secondary alkyl group R² is preferred. From the perspective of thermal stability, which affects distillation and other processes, a primary alkyl group is less prone to disproportionation and can be easily purified in some cases. On the other hand, secondary and tertiary alkyl groups are more prone to disproportionation reactions, and especially when the carbon number is low (6 or less), secondary and tertiary alkyl groups are often unstable and difficult to distill.

### [Substituted Group X]

Substituted group X is not limited in structure as long as it can undergo reactions such as hydrolysis, but preferred specific examples include halogen, OR′, and NR′₂ due to their high reactivity. Each R′ group may be the same or different, and is an organic group having 1 to 10 carbon atoms, which may be substituted with halogen, oxygen, nitrogen, or other heteroatoms. When there are multiple R′ groups in the molecule, they may have different structures or may be bonded to each other to form a cyclic structure. As examples of OR′ structures, alkoxy groups, carboxy groups, etc. can be given, and as examples of NR′₂ structures, dialkylamino groups, amide groups, etc. can be given. Among these, alkoxy groups and dialkylamino groups are preferred due to their high reactivity in hydrolysis. Specific examples of R′ groups include methyl, ethyl, propyl, isopropyl, butyl, isobutyl, sec-butyl, tert-butyl, tert-amyl, 2-methyl-pentyl, trifluoroethyl, trifluoromethyl, etc. An example of NR′₂ is 1-pyrrolidinyl, where the two substituents on nitrogen are bonded to form a 5-membered ring.

Preferred examples of substituted group X include alkyl groups or alkyl groups containing fluorine as the substituted group R′, from the perspective of low boiling point and stability. From the perspective of low boiling point, those with fewer carbon atoms are preferred, while from the perspective of thermal stability and stability against moisture, those with more carbon atoms are preferred. Preferred examples of substituted groups X, which balance these characteristics well, include OR′: tert-butoxy, tert-amyloxy, 2-methyl-pentyloxy, trifluoroethoxy, trifluoromethoxy, etc.; NR′₂: dimethylamino, diethylamino, methyl ethylamino, pyrrolidinyl, etc. Among these, dimethylamino and diethylamino are most preferred in terms of reactivity when used as resist materials, and in terms of balancing stability and reactivity, tert-butoxy, tert-amyloxy, and 2-methyl-pentyloxy are most preferred.

Additionally, the organic groups in R and the substituted group X in the molecule may be bonded to each other to form a cyclic structure. In such cases, compounds with the following structures can be given as examples:

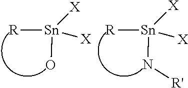

### [Tin Compound A1]

Among the aforementioned tin compounds, particularly preferred tin compounds for use in resist materials, etc. are compounds where a 4-valent tin is bonded to one organic group and three reactive substituent groups X that can undergo reactions such as hydrolysis. Specifically, these compounds are represented by formula (A1).

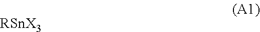

Tin compounds (A1) are prone to disproportionation reactions and the formation of multiple decomposition products due to their structural characteristics. Depending on the structure of the decomposition product, there are cases where it has a negative impact on the use of resist materials, etc., or further promotes decomposition during storage, and in such cases, it may be necessary to manage not only the purity of tin compounds (A1) but also the occurrence amount of each decomposition product. In other words, organic tin compounds are more difficult to store, and to store them properly, it is necessary to pay particular attention to the materials that come into contact with them to avoid promoting decomposition. As mentioned earlier, when storing liquid organic tin compounds, there is a greater concern about the leaching of metal components from the storage containers, requiring stricter management.

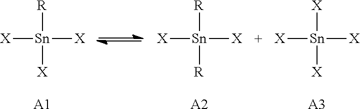

### [Purity of Tin Compounds]

The purity of organic tin compounds is not particularly limited, and it can be, for example, a mixture of tin compounds with different structures or a mixture containing organic tin compounds, solvents, additives, etc. On the other hand, when storing and using a single compound, it is preferable for the purity of organic tin compounds to be 95 mol % or higher in terms of tin atoms, as this allows for the use of high-purity resist materials. The purity of organic tin compounds is expressed in mol %, and is measured by the method described below. The higher the purity, the higher the purity of the resist material, and the performance of the resist improves. Therefore, it is more preferable for the purity to be 97 mol % or higher, particularly preferably 98 mol % or higher, further preferably 98.5 mol % or higher, and further preferably 99.0 mol % or higher. As for the upper limit of purity, it is preferably 99.99% or less, more preferably 99.9% or less, and further preferably 99.8% or less.

Here, the purity of organic tin compounds is expressed in mol % in terms of tin atoms, and represents the ratio of tin atoms of the target compound among all compounds containing tin atoms (including unidentified compounds). In practice, all peaks observed by ¹¹⁹Sn-NMR are summed as the denominator, and the integral value of the peak of the target compound is used as the numerator to calculate the purity. Following this calculation method, only compounds containing tin atoms are considered in the calculation.

The analysis method for ¹¹⁹Sn-NMR is performed without diluting the tin compound to improve sensitivity, and is acquired using a large number of accumulations (1000 or more, preferably 10,000 or more), sufficient relaxation time (1 second or more), and reverse gated decoupling conditions. As a result, by employing these methods, the detection limit for tin compounds can reach 0.01 mol %. Additionally, if the sensitivity of the measured peak is still insufficient, it is possible to further enhance detection sensitivity by using high-sensitivity NMR (e.g., 600 MHz NMR with a cryoprobe), allowing for detection at 0.001 mol %. On the other hand, in the case of tetraamino tin compounds, the peak may be broad, resulting in a larger detection limit compared to normal tin compounds. In such cases, it is sufficient to increase the number of accumulations, etc.

The following is a description of the storage container used in the present storage method.

### <Storage Container>

It is preferable for organic tin compounds to be stored in a specific container under conditions where air and water do not enter, ensuring a sealed environment. In particular, for the storage of tin compounds (I) and tin compounds (A1), which are highly reactive organic tin compounds with hydrolysable substituent groups, it is preferable to use a container made of a metal material such as iron, stainless steel (SUS), copper, or aluminum as the base material, which can be highly sealed, considering factors such as high sealing properties, pressure resistance, high strength, moldability, and cost. Here, “stainless steel (SUS)” refers to stainless steel (SUS) specified in international standards such as ISO 15510, Japanese standards such as JIS G4304 and G4305.

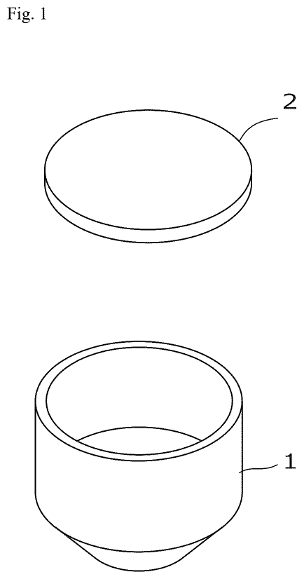

For example, as shown in FIG. 1, a container can be provided with a container body 1 that has a cylindrical side and a lower bottom in the shape of an inverted conical frustum, and a lid body 2 that seals the upper opening of the container body. These can be integrated by welding, etc.

[Material of the Part in Contact with Tin Compounds in the Storage Container]

For the material of the part in contact with tin compounds in the storage of organic tin compounds, the following characteristics are required, for example.
Container characteristics: Sufficient strength (pressure resistance, impact resistance depending on the purpose). The container can be molded into the desired shape. It has light-shielding properties. It has sealing properties (does not allow water or gas to pass through).
Storage stability of organic tin compounds: It does not react with the stored organic tin compounds. It does not promote decomposition reactions.
Stability of the container: There is no leaching of organic or inorganic components from the container. The container does not undergo changes such as corrosion.
Surface smoothness: Low surface area. The surface shape is highly uniform, resulting in fewer specific reaction points.
Economic factors: Practical cost, mass production capability, and the ability to be made large are required.

Cases where the material conditions are particularly important include when high-purity management, management of the content of each impurity, and management of trace metal content are required for the use of semiconductor materials, etc.; when the reactivity of organic tin compounds is high, thermal stability is low, or when they have hydrolysable substituent groups or substituent groups that react with water and air; when gases with combustibility, reactivity, corrosiveness, or toxicity are generated due to the decomposition of organic tin compounds; when organic tin compounds have combustibility or self-ignition properties and are subject to legal restrictions or constraints during storage and transportation; when organic tin compounds are in liquid form; when they have volatility at the storage temperature; or when they have corrosiveness or leaching properties against metals.

Specifically, it is preferable for the storage container used in the present storage method to be a sealed container, and for the parts in contact with organic tin compounds to have the following constitution.

### (Electropolished Stainless Steel (SUS-EP))

Electropolished stainless steel (hereinafter referred to as “SUS-EP”) is a method where, for example, stainless steel such as SUS316 is used as the anode in an electrolytic polishing solution (e.g., phosphoric acid solution), and direct current is passed through it to treat the surface. At this time, due to the properties of the electrolytic polishing solution, the protruding parts of the metal are preferentially dissolved, reducing roughness and resulting in a smooth, glossy surface. Additionally, the iron on the surface of the stainless steel is selectively dissolved, increasing the concentration of chromium (Cr) on the surface, which forms an oxide chromium film. Similarly, Ni and Mo also tend to increase on the surface. By using these surface characteristics as the parts in contact with organic tin compounds, it is possible to suppress reactions with organic tin compounds and suppress purity degradation. Furthermore, in some cases, the components of the electrolytic polishing solution used, such as phosphorus atoms, can be contained on the surface, and specifically, when a phosphoric acid solution is used as the electrolytic polishing solution, it is possible to suppress reactions with organic tin compounds or enhance corrosion resistance by containing phosphorus atoms on the surface. Therefore, it is preferable to use electropolished stainless steel (SUS-EP) as the material for the parts in the tin compound storage container. Among SUS-EP, SUS316-EP, which has excellent corrosion resistance, cost, and processability, is further preferable.

### (Elemental Composition Analysis of Stainless Steel Surface)

Elemental composition analysis of the stainless steel surface can be performed using, for example, X-ray photoelectron spectroscopy (XPS). It can be measured under the experimental conditions shown in the examples described below. When the elemental composition of the main elements (Cr, Fe, Ni, Mo, O) of stainless steel is set to a total of 100 using XPS, it is preferable for the ratio of Cr and Fe (Cr/Fe) to be high. As for the preferred value of Cr/Fe, it is preferably 0.30 or more, more preferably 0.35 or more, further preferably 0.40 or more, and further preferably 0.45 or more. As for the preferred value of Ni/Fe, it is preferably 0.05 or more, more preferably 0.07 or more, and further preferably 0.10 or more. As for the preferred value of Mo/Fe, it is preferably 0.03 or more. When the above values are within the preferred range, the chromium (Cr) concentration on the surface is sufficient, and it is possible to suppress reactions with organic tin compounds and suppress purity degradation in the present disclosure, making it a preferable material for the parts in the tin compound storage container. Similarly, when the concentration of Ni and Mo on the surface is within the above range, it is possible to further suppress reactions with organic tin compounds and suppress purity degradation, making it even more preferable.

As for the chromium elemental composition (at %) obtained by the aforementioned analysis method, it is preferably 7 at % or more, more preferably 9 at % or more, and further preferably 10 at % or more. When the above values are within the preferred range, the chromium (Cr) concentration on the surface is sufficient, and it is possible to suppress reactions with organic tin compounds and suppress purity degradation in the present disclosure, making it a preferable material for the parts in the tin compound storage container.

In the same analysis method, when the total of Cr, Fe, Ni, Mo, O, C, P, Ca, and Zn is set to 100 in the elemental composition, it is preferable for P (phosphorus) to be included at 0.1 at % or more, more preferably 0.3 at % or more, further preferably 0.5 at % or more, further preferably 0.8 at % or more, and further preferably 1.0 at % or more. By containing the preferred range of phosphorus on the surface, it is possible to suppress reactions with organic tin compounds or enhance corrosion resistance in some cases.

### (Depth Profile Analysis of Stainless Steel Surface Elements)

As an indicator to evaluate the chromium (Cr) concentration on the stainless steel surface, it is possible to use the value of Cr1/Cr2 obtained by depth profile analysis.

In the elemental composition analysis of the depth profile analysis of stainless steel by XPS, when Cr1: Maximum Cr composition (at %) in the range of depth 0 nm to 15 nm, when Cr2: Maximum Cr composition (at %) in the range of depth 15 nm to 30 nm, the preferred value of Cr1/Cr2 is 1.2 or more, more preferably 1.3 or more, further preferably 1.4 or more, particularly preferably 1.5 or more, and especially preferably 1.6 or more. The upper limit value is usually 5.0.

When the above values are within the preferred range, the chromium (Cr) concentration on the surface is sufficient, and it is possible to suppress reactions with organic tin compounds and suppress purity degradation, making it a preferable material for the parts in the tin compound storage container. Additionally, by having a chromium film on the surface, it functions as an inert film, suppressing corrosion by the tin compound and leaching of the stainless steel, making it preferable. Furthermore, when washing, it is possible to reduce the attachment of water or solvents, allowing for more effective washing to be performed, or reducing the residual amount of water or solvents used after washing. In addition, by having a chromium film only on the surface, it is possible to maintain the properties of the base material, such as the strength and sealing properties of the stainless steel, making it preferable.

### [Surface Roughness of Stainless Steel]

The surface roughness of stainless steel can be evaluated using the surface roughness parameters Sa (arithmetic average height) and Sq (root mean square height) defined in ISO 25178 surface characteristics (surface roughness measurement). These values can be measured, for example, by the method described in the examples below.

As for the surface roughness parameter Sa (arithmetic average height), it is preferably 500 nm or less, more preferably 300 nm or less, and further preferably 200 nm or less. The lower limit value is usually 0 nm. As for the surface roughness parameter Sq (root mean square height), it is preferably 500 nm or less, more preferably 300 nm or less, and further preferably 200 nm or less. The lower limit value is usually 0 nm.

When the roughness values are within the preferred range, the smoothness is high, the surface area is small, and there are fewer protruding parts that become specific reaction points, making it possible to suppress reactions with organic tin compounds and suppress purity degradation, and making it a preferable material for the parts in the tin compound storage container. Additionally, by having a smooth surface, it is possible to reduce the attachment of water or solvents when washing, allowing for effective washing to be performed, or reducing the residual amount of water or solvents used after washing.

The reduction of the surface roughness of stainless steel can be achieved by processing or post-processing of the stainless steel. For example, it can be achieved by combining polishing processes such as electrolytic polishing or buff polishing, rolling processes, heat treatment, and washing processes.

An article comprising an organic tin compound sealed in a container (C1), wherein the organic tin compound is an organic tin compound having formula (A1) with a purity of 95 mol % or more, the container (C1) is a sealed container, and the parts in contact with the organic tin compound are electropolished stainless steel, is useful for the manufacturing, purification, storage, transportation, transfer, and usage of high-quality organic tin compounds.

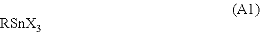

Additionally, when an inert gas is sealed in the container (C1), it is preferable as it suppresses the quality degradation of the organic tin compound. The preferred inert gas is nitrogen or argon.

An article comprising an organic tin compound sealed in a container (C2), wherein the organic tin compound is an organic tin compound having formula (A1) with a purity of 95 mol % or more, the container (C2) is a sealed container, and the parts in contact with the organic tin compound are stainless steel that meets the following condition 1, is useful for the manufacturing, purification, storage, transportation, transfer, and usage of high-quality organic tin compounds.

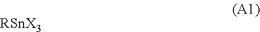

### (Condition 1)

In the elemental composition analysis of the stainless steel by XPS, if Cr1 represents the maximum Cr composition (at %) in the range of depth 0 nm to 15 nm, and Cr2 represents the maximum Cr composition (at %) in the range of depth 15 nm to 30 nm, Cr1/Cr2 is preferably 1.2 or more.

Additionally, when an inert gas is sealed in the container (C2), it is preferable as it suppresses the quality degradation of the organic tin compound. The preferred inert gas is nitrogen or argon.

### <Type and Purpose of the Container>

There is no particular limitation on the type and purpose of the container, but as a stainless steel storage container for semiconductor materials, for example, containers (CVD containers, precursor containers) used in the CVD process of semiconductors can be mentioned. The following is a description of the precursor container (CVD container).

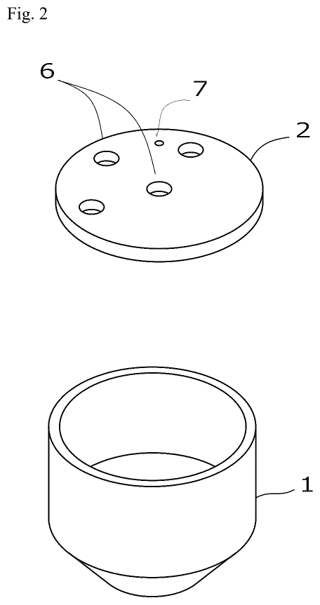

As a preferred embodiment of the present precursor container, for example, as shown in FIG. 2, a semiconductor manufacturing CVD precursor supply container with a cylindrical side and a lower bottom in the shape of an inverted conical frustum can be provided. These can be integrated by welding, etc.

The inner concave part of the container body 1 forms a space for accommodating the chemical.

The lower bottom of the inner surface shape (concave part) of the container body is preferably in the shape of an inverted conical frustum (or inverted cone). Since the side of the container is usually cylindrical, it is preferable for the overall shape of the container to be hopper-shaped, and it is more preferable for the bottom surface to be flat. This makes it possible to reduce the amount of precursor left over, and also makes it easier to clean the container. It is possible to minimize exposure to the external environment, as well as minimize the intrusion of foreign matter (contamination) and corrosion.

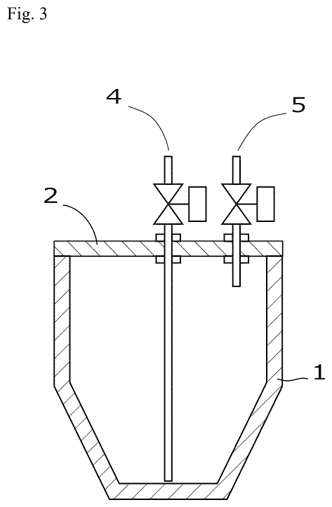

In FIG. 3, a longitudinal cross-sectional view of the entire precursor container composed of the container body 1 and the lid body 2 is shown. The lid body 2 is configured to be able to attach various components such as a discharge pipe 4 equipped with a liquid level sensor (not shown) or an injection pipe 5. It is preferable for multiple pipes and valves necessary for injection, discharge, gas insertion, and exhaust to be able to be connected. Additionally, when storing or transporting, it is preferable to replace the lid body with one that does not have holes for attaching various components. Note that there are differences in the shape and dimensions of the container and components, but these are not considered problematic.

In the present embodiment, it is necessary to heat the precursor to vaporize it, and when heating the precursor using the container body 1 itself, heating is usually performed from the bottom surface of the container body 1 using a heater, etc. In other words, it is preferable for the precursor container to have a structure that heats the bottom of the container body 1 with a heating source, or to be used together with a heating source.

When sending the precursor to the CVD device side, if the precursor container is a bubbling container, there is a possibility that the steam pressure will decrease due to the loss of vaporization heat when inserting gas from the outside for bubbling, or that the supply amount will change due to changes in pressure. Therefore, by having at least the inner side wall surface be a vacuum insulation structure, it is possible to minimize heat dissipation as much as possible.

Additionally, in the case of vaporizing the precursor by bubbling, even if the container does not have a heating source, it is possible to vaporize the precursor by bubbling after preheating the precursor in a separate container and transferring it to the present precursor container. However, if the vaporization heat is large, there may be a need to reheat, so it is preferable to have a heating source.

In the present embodiment, the heating source is usually installed at the bottom of the container, but when heat exchange is necessary, the heater is detached from the bottom of the container, and during heating, the vacuum part of the side wall acts as a heat insulator. This method is also effective for containers using the bubbling and baking methods.

In the case of a baking container, the precursor is directly heated and evaporated, so a carrier gas is usually unnecessary. However, to maintain the temperature of the container at a constant level, an insulating container with the same heat insulation effect is effective.

In the case of a completely sealed container, unless it is disposable, an inner surface inspection of the organic tin compound is performed when refilling the organic tin compound to maintain high purity. It is preferable to have a hole on the top surface (lid body) that can be observed with a borescope.

It is also possible to provide an outlet at the bottom of the precursor container. By providing an outlet, it is possible to perform sufficient cleaning even if there is a remaining amount of the precursor. Additionally, depending on the precursor used, there may be cases where the precursor solidifies (scales) during cleaning, and in such cases, it is preferable to perform internal cleaning with an acidic aqueous solution containing nitric acid or hydrofluoric acid, etc., once every few times. However, due to the metal leaching caused by nitric acid or hydrofluoric acid, it is preferable to have an outlet at the bottom when performing final cleaning with ultrapure water (preferably with a resistance value of 18 MΩ·cm). By having such an outlet, it is possible to circulate ultrapure water within the container, and also to prevent recontamination (contamination from the outside or the outer metal surface) by preventing ultrapure water (containing acidic aqueous solution) from overflowing outside the container (there is a possibility that the container will dissolve).

It is preferable for the lid of the outlet to have a flat surface on the container's inner side to prevent the generation of residue around the outlet.

If a joint part is provided in the opening and closing part of the lid body 2, it becomes a cause of contamination from the outside environment due to the packing or gasket attached when opening and closing the lid body 2. Therefore, to ensure the storage stability of the precursor used, it is preferable to make it possible to seal with the lid body 2.

The container body 1 and the lid body 2 may be integrally molded, or they may be separately manufactured. If they are separately manufactured, it is preferable to weld the container body 1 and the lid body 2 together to enhance sealing properties, and among them, it is further preferable to use an in-line (spigot) weld, etc., which cannot be opened.

The material of the container body 1 and the lid body 2 is stainless steel, and it is preferable to use an austenitic stainless steel alloy based on iron to make the surface smooth. More preferably, it is SUS316, SUS304, and further preferably, it is SUS316L that has been vacuum double melted. Additionally, as shown above, there are concerns about reactions and corrosion with the metals that make up the container depending on the precursor, and to avoid this, it is preferable to perform electrolytic polishing on the inner surface (parts in contact with organic tin compounds). By doing so, it is possible to provide a CVD precursor supply container with low residual chemicals, low thermal conductivity, and no electrostatic charge, which can be cleaned and reused.

When the contents come into direct contact with the metal of the container, especially when using an acidic aqueous solution, etc., for cleaning during washing, there is a concern about metal leaching, so it is preferable to choose SUS316L, which has been vacuum double melted and has almost the minimum amount of trace metal content, as the material for the inner surface.

The metal used for the lid body 2 is preferably the same metal used for the container body 1. However, it is not necessary for the materials of both to be identical. There are also lid bodies 2 that cannot be opened due to the in-line structure, etc., and there are also integrated types.

It is preferable to perform electrolytic polishing on the lower surface (the surface facing the upper opening of the container body 1) of the lid body 2 in the same manner as the electrolytic polishing performed on the container body 1 side, to maintain the purity of the chemicals within the container.

The lid body 2 usually has holes for the precursor inlet, the outlet of the vaporized precursor, and the hole 6 for attaching the level sensor, the hole 7 for attaching the electrode, etc., arranged in a predetermined configuration. The hole for observing the inner surface of the container with a borescope can be chosen from various convenient holes.

In particular, in the case of a completely sealed container, unless it is disposable, an inner surface inspection of the precursor is performed in advance with a borescope, etc., when refilling the precursor.

Additionally, in the case of a container for performing bubbling, an inlet for inert gas is also provided in the lid body 2. In this case, the inlet for the precursor for refilling and the inlet for inert gas can be used in common.

It is also possible to apply electrolytic polishing to the inner circumferential surface of the holes 6 and 7, etc., of the lid body 2 in the same manner as the lower surface of the lid body 2. By doing so, the inner circumferential surface of the holes 6, etc., becomes smooth, making it more suitable when attaching or detaching pipes or electrodes, as no metal scraps are generated, and it is less likely to attract external dust, etc.

The precursor container composed of the container body 1 and the lid body 2 may become high temperature, so it is preferable not to apply plastic coating, etc., to the stainless steel.

Therefore, to avoid metal leaching, it is preferable to use a material that has been vacuum double melted, especially SUS316L, and to perform electrolytic polishing on the inner surface to minimize metal leaching. Additionally, from the perspective of reuse, if the precursor solidifies (scales) inside, especially in the case of having a coating, it is possible to wash with, for example, a 40% nitric acid aqueous solution or hydrofluoric acid of an arbitrary concentration.

In addition, in the case of a hopper-shaped container, the shape of the container body 1 is a bottomed cylinder, making it easier to wash, and it is possible to clean the inside of the container in a short time. Since it is difficult for liquid to accumulate, and there is little residue of the contents, it is also suitable for inspecting residues after washing with a borescope. Therefore, by using the present precursor container to handle chemicals for semiconductor manufacturing, it is possible to repeatedly and stably provide high-quality semiconductor products. Additionally, it is possible to avoid the risk of holding or transporting the precursor in a state where there are residues, and it is also possible to efficiently wash and reuse the container.

Therefore, when storing or transporting the precursor in this container for a long period, it is possible to almost completely prevent the metal of the container body 1 side from leaching into the precursor, peeling off, or introducing foreign matter due to electrostatic charge.

From the above, by using the container of the present embodiment for chemical supply in the CVD process, it is possible to avoid the occurrence of defective products due to purity degradation of the chemicals, and it is possible to manufacture high-quality semiconductors with high yield.

By using the present precursor container, it is possible to vaporize the precursor by bubbling or baking, and stably supply the vaporized precursor to the CVD device, and uniformly and homogeneously deposit the precursor within the CVD device.

Therefore, by using the present precursor container to handle the precursor, it is possible to repeatedly and stably provide high-quality semiconductor products.

### <Cleaning of the Storage Container>

It is preferable to clean the storage container before using it for storing tin compounds, and then use it after drying. Specifically, by washing with organic solvents such as acetone or hexane, it is possible to remove organic components and moisture that are involved in the decomposition of organic tin compounds, making it preferable.

The chemicals that can be used as the washing liquid are liquids with fluidity, and for example, the following various chemicals can be mentioned.

For example, hexane, heptane, toluene, etc., as hydrocarbon solvents; methanol, ethanol, isopropanol, etc., as alcohol solvents; acetone, methyl isobutyl ketone, etc., as ketone solvents; acidic aqueous solutions such as nitric acid aqueous solution, hydrofluoric acid aqueous solution, hydrochloric acid aqueous solution, and sulfuric acid aqueous solution; basic aqueous solutions such as sodium hydroxide aqueous solution and ammonium hydroxide aqueous solution; deionized water, ultrapure water (preferably with a resistance value of 18 MΩ·cm), etc. These can be used alone or in combination of two or more.

Among them, it is preferable to include a process of washing with an acidic aqueous solution and a process of washing with ultrapure water. By washing with acidic aqueous solution or ultrapure water, there is a possibility of being able to remove organic components and inorganic components on the surface, and there is a possibility of being able to suppress decomposition when storing tin compounds. Additionally, electropolished stainless steel and stainless steel with high chromium (Cr) surface concentration are more easily removed from the aforementioned organic components, inorganic components, and moisture, so it can be said that the effect of washing is higher. Also, the concentration of chemicals in the aqueous solution, such as nitric acid aqueous solution, is preferably 0.1 to 40% by mass.

### <Reutilization Method of the Storage Container>

The storage container has excellent wear resistance, corrosion resistance, heat resistance, and thermal insulation properties, so it is possible to wash and reuse the container after use. As a method for reusing the storage container after using it, it is preferable to wash the container with a washing liquid before putting in new organic tin compounds again. This makes it possible to maintain high purity of the organic tin compounds. The washing liquid is preferably the aforementioned washing liquid.

Additionally, in the case of organic tin compounds that cause scaling, it is preferable to wash with an acidic aqueous solution, and then further wash with an alkaline solution. As the alkaline solution, sodium hydroxide, which makes it easy to remove scale, etc., is preferable. By doing so, it is possible to wash with an alkaline solution to remove dirt that cannot be removed with an acidic aqueous solution.

### <Application>

The storage container has excellent wear resistance, corrosion resistance, heat resistance, and thermal insulation properties, so it is suitable for precursors that are in a liquid state or have a low melting point, have vapor pressure, and are heated and vaporized within the container to be supplied to the CVD device. It is suitable for storage and transportation in bubbling and baking.

In the case of storage, it is possible to preserve the precursor by sealing a noble gas (rare gas) or a mixture of noble gases used for bubbling. It is also possible to store it for a certain period of time, and also to transport it.

A storage method according to embodiments of the disclosure comprises sealing the organic tin compound having formula (A1) in the container (C2) that has been cleaned by a method including the following steps 1 and 2:
step 1: cleaning with acidic aqueous solution; and
step 2: cleaning with ultrapure water.

A storage method for the article described herein comprises cleaning the container (C2) by a method including the following steps 1 and 2 after removing the organic tin compound having formula (A1) from the article, and then re-sealing the organic tin compound having formula (A1) in the container (C2);
step 1: cleaning with acidic aqueous solution; and
step 2: cleaning with ultrapure water.

### <Manufacturing Method of Coating Liquid>

The monoalkyltin compound of this disclosure can be taken out of (removed from) the container and directly deposited on a substrate as a photoresist precursor using a CVD apparatus. Alternatively, the monoalkyltin compound can be extracted from the container, dissolved in a solvent to produce a coating liquid, and then spin-coated onto a substrate to form a film

Preferred solvents for manufacturing the coating liquid include alcohols, aromatic and aliphatic hydrocarbons, esters, or combinations thereof. Particularly suitable solvents are xylene, toluene, anisole, tetrahydrofuran, propylene glycol monomethyl ether acetate, ethyl acetate, ethyl lactate, 4-methyl-2-propanol, 1-heptanol, 1-hexanol, 1-pentanol, 1-butanol, methanol, isopropyl alcohol, 1-propanol, methyl ethyl ketone, and mixtures thereof. Among these, propylene glycol monomethyl ether acetate, 4-methyl-2-propanol, and 1-heptanol are preferred for their coating properties and safety

It is preferable to manufacture the coating liquid under an inert gas atmosphere such as nitrogen or rare gases, preferably nitrogen, helium, or argon, and more preferably argon.

### <Semiconductor Pattern Formation Method>

When applying the storage container and monoalkyltin compound precursor container of this disclosure to a semiconductor pattern formation method, the following main steps are performed:

### (i) Liquid Preparation Step

Extract the monoalkyltin compound from the precursor container and mix it with solvents and additives. This step can be omitted if the precursor is used directly in semiconductor manufacturing.

### (ii) Transfer Step

Transfer the contents of the precursor container, after the liquid preparation process if necessary, to the supply tank of the semiconductor manufacturing equipment. The contents may be transferred to another container before being moved to the supply tank.

(iii) Thin Film Formation Step

The precursor transferred to the supply tank is formed as a uniform thin film on a wafer using chemical vapor deposition (CVD) or spin coating. By co-existing compounds that promote hydrolysis, such as water, the monoalkyltin compound can be hydrolyzed in situ to form a resist film composed of partially polymerized tin oxohydroxo forms.

### (iv) Exposure Step

The formed resist film is then pattern-exposed by irradiating it using actinic radiation such as DUV, EUV, or EB, forming a latent image as the exposed parts chemically change.

### (v) Development Step

The exposed latent image pattern is developed by dry or wet development to form a resist pattern.

### (vi) Etching Step

After development, the remaining resist pattern is used as a mask to etch the substrate, forming fine patterns on the substrate.

### Examples

The following is a more detailed description of the present invention with reference to examples. However, the present invention is not limited to these examples.

### <Preparation of Test Pieces>

As test pieces, SUS316 (surface finish No. 2B according to JIS G 4304), SUS316-EP (electropolished SUS316), and SUS304 (surface finish No. 2B) were purchased from GokouSeisakusho Co., Ltd., respectively. The dimensions of each are as follows.
SUS316: 30 mm×10 mm×2 mm
SUS316-EP: 50 mm×25 mm×2 mm
SUS304: 30 mm×10 mm×2 mm

### <Elemental Composition Analysis>

The surface composition analysis of SUS test pieces was performed using X-ray photoelectron spectroscopy (XPS). The measurement conditions are shown below.

### [Surface Elemental Composition Analysis]

XPS measurement device: KRATOS ULTRA2 manufactured by Shimadzu Corporation
X-ray source: monochromatic A1-Kα line
Output: 15 kV-300 W (20 mA)
Charge neutralization: none
Spectrometer: pass energy value 80 eV
Measurement area: 110 μm diameter
Take-off angle (from the surface): 90°
Sample holding: conductive carbon tape
Energy correction method: energy position of the C is peak top derived from carbon C—C, C—H contamination carbon=284.8 eV

### [Depth Profiling Elemental Composition Analysis]

Depth profiling elemental composition analysis was performed by alternately performing Ar ion sputtering and XPS narrow spectrum measurement using the same device.
Acceleration voltage 4 kV
Ar ion sputtering rate: measured value of SiO₂ thin film (8.0 nm/min)

### [Analysis of Measurement Results]

### Analysis Software: ESCApe Manufactured by Shimadzu Corporation

Peak analysis conditions: after background removal processing based on the Shirley method for each element's photoelectron peak, the area intensity was obtained, and the elemental concentration was calculated using the relative sensitivity correction coefficient provided by the device manufacturer
Reference materials for chemical state: NIST X-ray Photoelectron Spectroscopy Database (SRD 20), Version 5.0

### [Surface Composition Analysis Results]

The results of the surface elemental composition analysis obtained by the aforementioned XPS wide spectrum analysis of each test piece surface are shown in Tables 1 and 2.

Table 1 shows the XPS surface elemental composition (at %) when the total of Cr, Fe, Ni, Mo, 0, C, P, Ca, Zn is set to 100.

Table 2 shows the XPS surface elemental composition (at %) when the total of Cr, Fe, Ni, Mo, 0 is set to 100 (limited to the main metal elements of SUS316).

TABLE 1
XPS surface elemental composition (at %) when the total
of Cr, Fe, Ni, Mo, O, C, P, Ca, Zn is set to 100.

| Test piece | Cr | Fe | Ni | Mo | O | C | P | Ca | Zn | Total |
|---|---|---|---|---|---|---|---|---|---|---|
| SUS316-EP | 6.9 | 12.8 | 1.3 | 0.4 | 39.9 | 37.1 | 1.0 | 0.5 | 0.2 | 100 |
| SUS316 | 3.3 | 12.0 | 0.5 | 0.3 | 37.8 | 45.2 | — | 0.7 | 0.3 | 100 |

TABLE 2
XPS surface elemental composition (at %) when
the total of Cr, Fe, Ni, Mo, O is set to 100
(limited to the main metal elements of SUS316).

| Test piece | Cr | Fe | Ni | Mo | O | Total | Cr/Fe | Ni/Fe | Mo/Fe |
|---|---|---|---|---|---|---|---|---|---|
| SUS316- | 11.2 | 20.9 | 2.1 | 0.7 | 65.2 | 100 | 0.54 | 0.10 | 0.03 |
| EP | | | | | | | | | |
| SUS316 | 6.1 | 22.3 | 0.9 | 0.5 | 70.2 | 100 | 0.27 | 0.04 | 0.02 |

From the surface elemental analysis (measurement depth <10 nm) by XPS, it was found that the composition of Cr was higher in SUS316-EP. This is also evident from the ratio of Cr to Fe, which is the main component metal of SUS316. The Cr component detected in larger amounts from SUS316-EP is presumed to be mainly Cr³⁺, and similarly, since oxygen atoms are detected in larger amounts on the surface, it is presumed that the main component is chromium oxide (Cr₂O₃). That is, it was found that the surface of SUS316-EP has a large amount of chromium oxide.

### [Depth Profiling Elemental Composition Analysis Results]

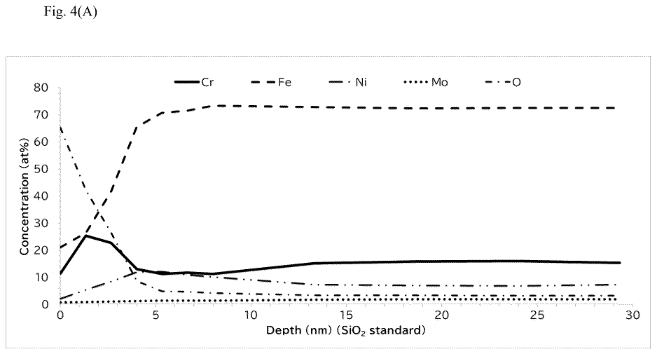

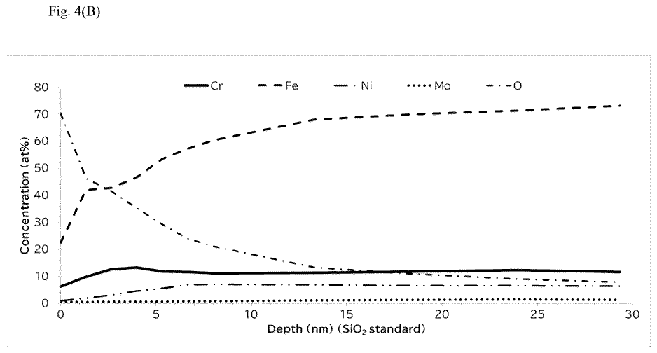

Based on the above-mentioned depth profiling elemental composition analysis method, a total of 220 seconds of Ar sputtering was performed. The sputtering depth (nm) converted to SiO₂ standard and the elemental composition (at %) at each sputtering time are shown in FIG. 4(A) and FIG. 4(B).

From the results of the depth profiling elemental composition analysis (depth direction composition analysis) shown in FIG. 4(A) and FIG. 4(B), it was found that SUS316-EP had a higher composition of Cr in the range close to the surface of 0 to 15 nm, similar to the results of the surface composition analysis. On the other hand, in the range of 15 to 30 nm, SUS316-EP showed a composition similar to SUS316, and it is presumed that it has the same composition as SUS316 except for the surface. The analysis results of SUS316-EP, which has more Cr in the surface than the interior, can also be judged from the following values of Cr1/Cr2.

### [Values of Cr1/Cr2]

Cr1: Maximum Cr composition (at %) in the range of depth 0 nm to 15 nm,
Cr2: Maximum Cr composition (at %) in the range of depth 15 nm to 30 nm
   The values of Cr1/Cr2 are as follows:

$$SUS 316 - EP : Cr 1 / Cr 2 = 25 / 16 = 1.6$$

$$SUS 316 : Cr 1 / Cr 2 = 13 / 12 = 1.1$$

### <Surface Roughness Measurement>

Surface roughness measurement was performed using a scanning white interference microscope (VS1530 manufactured by Hitachi High-Tech Corporation), and the surface roughness parameters Sa (arithmetic average height) and Sq (root mean square height) defined in ISO 25178 surface characteristics (surface roughness measurement) were measured. The measurement values are shown in Table 3.

TABLE 3

| Roughness | Sa (nm) | Sq (nm) |
|---|---|---|
| SUS316EP | 137 | 172 |
| SUS316 | 90 | 114 |

From this value, it was found that both SUS316 (surface finish No. 2B according to JIS G 4304) and SUS316-EP (electropolished SUS316) were flat with roughness (Sa, Sq) of 200 nm or less.

### <Preparation of Tin Compound (A1)>

A composition containing isopropyltris(dimethylamino)tin (1A) was prepared as the tin compound (A1) used for the storage test using the following manufacturing method. The purity of the obtained isopropyltris(dimethylamino)tin (1A) corresponds to the purity of “Before Storage Test” in Table 4-2.

A reaction vessel (200 L glass reaction vessel) and a stirring device (stirring blade: twin star, diameter: 350 mm, width 110 mm) were used for the reaction. The reaction vessel was replaced with nitrogen three times under reduced pressure. Special grade hexane (36.6 kg, moisture 30 ppm) and n-butyllithium (41.0 kg, 96.8 mol, 15% hexane solution, 3.09 eq) were added, and dimethylamine (8.69 kg, 193.6 mol, 6.18 eq) was dropped in while maintaining the temperature between−5 and 10° C. while stirring at 150 rpm.

The resulting slurry of dimethyl lithium amide was stirred for 5 hours at 23° C. to 27° C. The resulting slurry of dimethylamide was adjusted to 0° C., and a hexane solution of isopropyltrichlorotin (8.40 kg, 31.3 mol, 1.00 eq, purity over 99.9 mol %) was dropped in at a constant speed from a glass dropping device while maintaining the internal temperature at 0 to 10° C. over 3 hours. After addition, the temperature was raised to 20 to 25° C. and maintained at that temperature while stirring for 16 hours. The obtained reaction liquid was filtered using a pressure filter, and a transparent filtrate was obtained by removing the white solid (LiCl). The white solid was further washed with dehydrated hexane (7.3 kg×3), and the filtrates were combined.

After concentrating the obtained reaction liquid under reduced pressure, a crude tin compound containing isopropyltris(dimethylamino)tin (TA) was obtained at 9.3 kg. The obtained crude tin compound was distilled under reduced pressure (glass single distillation apparatus wrapped with a shading cloth, internal temperature: 70 to 80° C., degree of vacuum: 0.3 kPa) to obtain the corresponding tin compound at 6.1 kg as the distillate.

### <SUS Storage Test>

### [Test Piece Washing Method]

For some of the examples, the following washing method was performed.
(1) The test piece was immersed in hexane for 1 minute, and then air-dried.
(2) Next, the test piece was immersed in a 10% HNO3 aqueous solution for 1 minute.
(3) Next, the test piece was immersed in ultrapure water (resistance value of 18 MΩ·cm) for 1 minute, and then the test piece was washed with ultrapure water and air-dried with an air gun.

### [Storage Test Method]

The conditions for the storage test corresponding to each example and comparative example are shown in Table 4-1 below. A brown glass container (screw-cap bottle Duran) with a screw-type cap that can be sealed was used as the storage container, and when storing, the storage container was further placed in a light-shielding container made of polystyrene, and light-shielding storage was performed. The storage container was stored for one month under two temperature conditions: 0 to 10° C. refrigeration condition and 15 to 25° C. room temperature condition.

TABLE 4-1

| | Test | | Storage |
|---|---|---|---|
| | Piece Type | HNO₃ Washing | Temperature |
| Example 1 | SUS316-EP | Washed | 0~10° C. |
| Example 2 | SUS316-EP | Not washed | 0~10° C. |
| Example 3 | SUS316-EP | Washed | 15~25° C. |
| Example 4 | SUS316-EP | Not washed | 15~25° C. |
| Comparative Example 1 | SUS316 | Not washed | 15~25° C. |
| Comparative Example 2 | SUS304 | Not washed | 15~25° C. |

### [Preparation of Storage Samples]

In a glove box under an N₂ gas atmosphere, a test piece and about 10 mL of tin compound (1) were placed in the storage container. As a result, the test piece was in a state where more than half of it was immersed. In that state, the cap of the storage container was closed, and it was sealed under an N₂ gas atmosphere.

[Analysis of Samples after Storage]

The purity of the tin compound (A1) before the storage test and the tin compound (A1) after each storage test was analyzed by ¹¹⁹Sn-NMR. The analysis results are shown in Table 4-2. Note that the structures of the identified compounds are as follows, and the unit of the content is “mol %.”

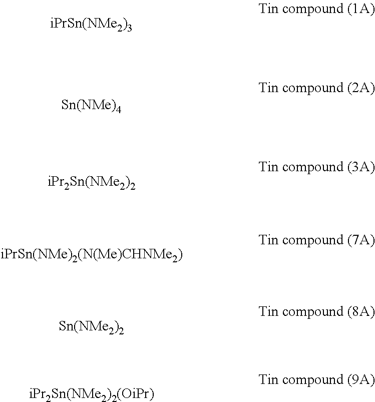

TABLE 4-2

| | | | | iPr | | | | |
|---|---|---|---|---|---|---|---|---|
| Chemical | Sn(NMe₂)₂ | (iPr)₂Sn(NMe₂)₂ | Unknown | Sn(NMe₂)₃ | | Unknown | Unknown | |
| structure | (8A) | (3A) | impurity | (1A) | (7A) | impurity | impurity | (9A) |
| ¹¹⁹Sn-NMR | 120 | −18 | −38 | −64 | −82 | −88 | −98 | −104 |
| chemical | | | | | | | | |
| shift (ppm) | | | | | | | | |
| Before | 0.00% | 0.24% | 0.00% | 99.18% | 0.57% | — | — | — |
| storage test | | | | | | | | |
| Example 1 | 0.00% | 0.21% | 0.00% | 99.22% | 0.57% | — | — | — |
| Example 2 | 0.00% | 0.22% | 0.03% | 99.07% | 0.67% | — | — | — |
| Example 3 | 0.00% | 0.23% | 0.00% | 99.04% | 0.73% | — | — | — |
| Example 4 | 0.00% | 0.23% | 0.11% | 98.98% | 0.68% | — | — | — |
| Comparative | 0.00% | 0.24% | — | 91.22% | 6.31% | 0.04% | 0.03% | 0.81% |
| Example 1 | | | | | | | | |
| Comparative | 0.00% | 0.25% | — | 90.31% | 7.02% | 0.06% | 0.05% | 0.83% |
| Example 2 | | | | | | | | |

| Chemical | Sn(NMe₂)₄ | Unknown | Unknown | Unknown | Unknown | Unknown | | |
|---|---|---|---|---|---|---|---|---|
| structure | (2A) | impurity | impurity | impurity | impurity | impucity | Total | Difference |
| ¹¹⁹Sn-NMR | −119 | −134 | −136 | −144 | −146 | −161 | | |
| chemical | | | | | | | | |
| shift (ppm) | | | | | | | | |
| Before | — | — | — | — | — | — | 100.00% | 0.00% |
| storage test | | | | | | | | |
| Example 1 | — | — | — | — | — | — | 100.00% | 0.04% |
| Example 2 | — | — | — | — | — | — | 100.00% | −0.11% |
| Example 3 | — | — | — | — | — | — | 100.00% | −0.14% |
| Example 4 | — | — | — | — | — | — | 100.00% | −0.20% |
| Comparative | 0.13% | 0.52% | 0.42% | 0.04% | 0.14% | 0.09% | 99.99% | −7.96% |
| Example 1 | | | | | | | | |
| Comparative | 0.16% | 0.51% | 0.48% | 0.04% | 0.16% | 0.12% | 99.99% | −8.87% |
| Example 2 | | | | | | | | |

Also, the mass change of the test piece under the storage conditions of Examples 1 to 4 is shown in Table 4-3 below.

TABLE 4-3

| | Test Piece | Test Piece | | |
|---|---|---|---|---|
| | Mass Before | Mass After | Mass Change | Change Rate |
| | Test (g) | Test (g) | (g) | (%) |
| Example 1 | 18.2376 | 18.2365 | −0.0011 | −0.0060 |
| Example 2 | 18.3145 | 18.3141 | −0.0004 | −0.0022 |
| Example 3 | 18.2652 | 18.2645 | −0.0007 | −0.0038 |
| Example 4 | 18.2836 | 18.2827 | −0.0009 | −0.0049 |

Also, the amount of metal derived from stainless steel contained in the tin compound (A1) under the storage conditions of Example 1 (content: mass ppb) was measured by ICP-MASS analysis. The measurement results are shown in Table 4-4 below.

TABLE 4-4

| | Content [mass ppb] | Content [mass ppb] |
|---|---|---|
| Element | Before Storage | Example 1 |
| Cr | <1 | <1 |
| Fe | <1 | <1 |
| Mn | <1 | <1 |
| Mo | <1 | <1 |
| Ni | <1 | <1 |

As shown in Table 4-2, in the storage test of SUS316-EP with electrolytic polishing performed in Examples 1 to 4, the purity of isopropyltris(dimethylamino)tin (1A) decreased very little, and it was possible to store it for one month while maintaining high purity.

On the other hand, in Comparative Examples 1 and 2, where electrolytic polishing was not performed on SUS316 and SUS304, the decomposition of isopropyltris(dimethylamino)tin (1A) was significant, and about 8% decomposition was observed after one month of storage, and many types of impurities were generated. Furthermore, in the examples, the decomposition was further suppressed in the storage at 0 to 10° C. shown in Examples 1 and 2. Also, when the specific washing operation shown in Examples 1 and 3 was performed, the decomposition was further suppressed.

In Examples 1 to 4, no change was observed in the appearance of coloring or cloudiness of tin compound (1A) before and after storage (in Examples 1 to 4, before storage: APHA <30, transparent, after storage: APHA <30, transparent).

As can be seen from Table 4-3, the mass change of the test piece in Examples 1 to 4 was within ±0.01%, and the mass change of the test piece due to leaching or corrosion was extremely small, and no change was observed in the appearance. Also, as can be seen from Table 4-4, in the tin compound (1A) after storage in Example 1, no leaching was observed for metal elements derived from stainless steel, which were detected at less than 1 ppb.

In the above examples, specific embodiments of the present invention were shown, but the above examples are merely examples, and should not be interpreted in a limiting manner. Various modifications that are obvious to those skilled in the art are intended to be included within the scope of the present disclosure.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1. An article comprising an organic tin compound sealed in a container (C1), wherein the organic tin compound has formula (A1) with a purity of 95 mol % or higher, the container (C1) is a sealed container, and a part of the container in contact with the organic tin compound is electrolytically polished stainless steel: 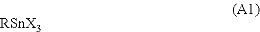
wherein R is an organic group having 1 to 30 carbon atoms which may be substituted with a halogen, oxygen atom, or nitrogen atom, X is selected from a halogen atom, OR′, or NR′₂, each R′ group may be the same or different and is an organic group having 1 to 10 carbon atoms which may be substituted with a halogen, oxygen atom, or nitrogen atom; when there are multiple R′ groups in the molecule, they may have different structures from each other or may be bonded to form a cyclic structure, and R and one X may be bonded to have a cyclic structure.

2. The article according to claim 1, wherein an inert gas is enclosed in the container C1.

3. An article comprising an organic tin compound sealed in a container (C2), wherein the organic tin compound has formula (A1) with a purity of 95 mol % or higher, the container (C2) is a sealed container, and a part of the container in contact with the organic tin compound is a stainless steel container that satisfies Condition 1: 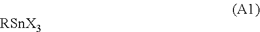
wherein R is an organic group having 1 to 30 carbon atoms which may be substituted with a halogen, oxygen atom, or nitrogen atom, X is selected from a halogen atom, OR′, or NR′₂, each R′ group may be the same or different and is an organic group having 1 to 10 carbon atoms which may be substituted with a halogen, oxygen atom, or nitrogen atom; when there are multiple R′ groups in the molecule, they may have different structures from each other or may be bonded to form a cyclic structure, and R and one X may be bonded to have a cyclic structure;
Condition 1:
wherein in an elemental composition analysis of the stainless steel by XPS, when Cr1 is a maximum Cr composition (at %) in a depth range of 0 nm to 15 nm, and Cr2 is a maximum Cr composition (at %) in a depth range of 15 nm to 30 nm, Cr1/Cr2 is 1.2 or more.

4. The article according to claim 3, wherein an inert gas is enclosed in the container C2.

5. The article according to claim 4, wherein the inert gas is argon.

6. The article according to claim 3, wherein in a surface elemental analysis of the stainless steel by XPS, a composition ratio (at %) of Cr to Fe is 0.30 or more.

7. The article according to claim 3, wherein in a surface elemental analysis of the stainless steel by XPS, when a total amount of Cr, Fe, Ni, Mo, and O is set to 100 (at %), an amount of Cr is 7 (at %) or more.

8. The article according to claim 3, wherein the stainless steel is SUS316.

9. The article according to claim 3, wherein a surface roughness Sa (arithmetic mean height) of the stainless steel is 200 nm or less.

10. The article according to claim 3, wherein a surface roughness Sq (root mean square height) of the stainless steel is 200 nm or less.

11. The article according to claim 3, wherein the container (C2) has two or more valves.

12. The article according to claim 3, wherein the container (C2) is a container for supplying the organic tin compound having formula (A1) by connecting the container to a CVD apparatus.

13. A storage method for the article according to claim 3, the method comprising storing the article at about 0° C. to about 25° C.

14. A storage method for the article according to claim 3, comprising sealing the organic tin compound having formula (A1) in the container (C2) that has been cleaned by a method including the following steps 1 and 2:
step 1: cleaning with acidic aqueous solution; and
step 2: cleaning with ultrapure water.

15. A storage method for the article according to claim 3, comprising cleaning the container (C2) by a method including the following steps 1 and 2 after removing the organic tin compound having formula (A1) from the article, and then re-sealing the organic tin compound having formula (A1) in the container (C2):
step 1: cleaning with acidic aqueous solution; and
step 2: cleaning with ultrapure water.

16. A method for storing an organic tin compound by putting it in a container (C1), wherein the organic tin compound has formula (A1) with a purity of 95 mol % or higher, the container (C1) is a sealed container, and a part of the container in contact with the organic tin compound is electrolytically polished stainless steel. 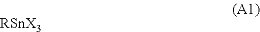
wherein R is an organic group having 1 to 30 carbon atoms which may be substituted with a halogen, oxygen atom, or nitrogen atom, X is selected from a halogen atom, OR′, or NR′₂, each R′ group may be the same or different and is an organic group having 1 to 10 carbon atoms which may be substituted with a halogen, oxygen atom, or nitrogen atom; when there are multiple R′ groups in the molecule, they may have different structures from each other or may be bonded to form a cyclic structure, and R and one X may be bonded to have a cyclic structure.

17. A method for manufacturing a coating liquid, comprising removing the organic tin compound having formula (A1) from the article of claim 3 and mixing it with an organic solvent.

18. A method for forming a pattern of a semiconductor, comprising a step of forming a thin film by applying the coating liquid manufactured by the method of claim 17 on a substrate, a step of irradiating the thin film with actinic radiation, and a step of developing the exposed thin film.

19. A method for forming a pattern of a semiconductor, comprising a step of removing the organic tin compound having formula (A1) from the article of claim 3 and forming a thin film by depositing it on a substrate, a step of irradiating the thin film with actinic radiation, and a step of developing the exposed thin film.
